(19) United States
(12) Patent Application Publication
(10) Pub. No.: US 2014/0203381 A1
(43) Pub. Date: Jul. 24, 2014

(54) PROCESS AND APPARATUS FOR TRANSFORMING NITRIDATION/OXIDATION AT EDGES, AND PROTECTING EDGES OF MAGNETORESISTIVE TUNNEL JUNCTION (MTJ) LAYERS

(71) Applicant: QUALCOMM INCORPORATED, San Diego, CA (US)

(72) Inventors: Xiaochun Zhu, San Diego, CA (US); Xia Li, San Diego, CA (US); Wei-Chuan Chen, Taipei (TW); Seung H. Kang, San Diego, CA (US)

(73) Assignee: QUALCOMM INCORPORATED, San Diego, CA (US)

(21) Appl. No.: 13/748,979

(22) Filed: Jan. 24, 2013

(51) Int. Cl. H01L 43/12; H01L 43/02

(52) U.S. Cl. CPC H01L 43/12; H01L 43/02
USPC 257/421; 438/3; 156/345.1

(57) ABSTRACT

Material surrounding a magnetic tunnel junction (MTJ) device region of a multi-layer starting structure is etched, forming an MTJ device pillar having an MTJ layer with a chemically damaged peripheral edge region. De-nitridation or de-oxidation, or both, restore the chemically damaged peripheral region to form an edge-restored MTJ layer. An MTJ edge restoration assist layer is formed on the edge-restored MTJ layer. An MTJ-edge-protect layer is formed on the insulating MTJ-edge-restoration-assist layer.

### FIELD OF DISCLOSURE

The technical field of the disclosure relates to fabrication and structure of magneto-resistive elements in magnetic tunnel junction (MTJ) memory cells.

### BACKGROUND

MTJ is considered a promising technology for next generation non-volatile memory. Potential benefits include fast switching, high switching cycle endurance, low power consumption, and extended unpowered archival storage.

One conventional MTJ element has a fixed magnetization layer (alternatively termed “pinned” or “reference” layer), and a “free” magnetization layer, separated by a tunnel barrier layer. The free layer is switchable between two opposite magnetization states, with one being “parallel” (P) to the magnetization of the fixed layer, and the other being opposite, or anti-parallel” (AP), to the fixed magnetic layer. The MTJ element is termed “magneto-resistive” because when in the P state its electrical resistance is lower than when in the AP state. By injecting a write current, the magnetization of the MTJ free layer can be switched between the P and AP states. The direction of the write current is determinative of the state. The P and AP states can correspond to a “0” and a “1,” i.e., one binary bit, by injecting a reference current and detecting the voltage.

Materials and structure of the fixed layer and free layer are directed to impart these layers with certain ferromagnetic properties. Known techniques of fabricating MTJ elements include etching a large area multilayer structure, having the constituent layers for what will become an array of MTJ elements. The etching can entail forming an array of etch-resistant elliptical areas on the surface of the large area multilayer structure, for example by photomask. Various etching processes are applied to remove the multi-layer structure between the elliptical areas, leaving an array of elliptical pillars, each being a stack of the constituent layers of the starting large area multilayer structure. Because of the staking order of the constituent layers, their respective thicknesses, and respective electrical, ferromagnetic, and/or insulating properties, each pillar is an MTJ element.

However, certain processes used in known techniques of fabricating MTJ elements, for example the above-described etching of a large area multi-layer structure having ferromagnetic and other layers in an MTJ stacking order, can result in chemical damage at formed edges of the ferromagnetic layers. This may have a depth establishing what can be termed “chemically damaged edge region(s)” extending inward from the etched edges. These chemically damaged edge regions generally have ferromagnetic properties different from those of the free or fixed layer as deposited. Various costs, such as device yield, design rule constraints, and requirements for compensating measures, can be incurred.

### SUMMARY

One exemplary embodiment provides a method for repairing or reducing chemical damage to an edge region of a magnetic tunnel junction layer. Example methods according to this and other exemplary embodiment may include forming the magnetic tunnel junction layer having the edge region with a chemical damage, and transforming at least a portion of the edge region with the chemical damage to a chemically restored edge portion.

In one aspect, the forming may form the chemical damage to include an oxidation material, a nitridation material, or both, and wherein the transforming includes a de-oxidation, a de-nitridation, or de-water, or any combination thereof.

In an aspect, transforming in accordance with the exemplary embodiment may include applying a processing temperature raising the edge region with the chemical damage, while the edge region is exposed, to a temperature above 200 degrees C. In another aspect, the transforming may include an annealing process.

In one aspect, the transforming may be performed until the edge region with the chemical damage is transformed to a chemically restored peripheral edge region of the magnetic tunnel junction layer.

In another aspect, the transforming may include transforming the chemically restored peripheral edge region into a chemically restored and protected edge region, by forming an insulating MTJ-edge-restoration-assist layer to surround the chemically restored and protected edge region.

In an aspect, the forming may include an etching, and wherein at least a portion of the transforming may be performed concurrently with the etching, wherein the portion may comprise injecting H₂ in a manner to react at a location of the etching and pull an oxidation material formed by the etching.

Example methods according to one or more exemplary embodiments may provide, or form, the magnetic tunnel junction layer to include iron (Fe), cobalt (Co), or both, and may arrange the magnetic tunnel junction layer facing a tunnel barrier layer having magnesium oxide (MgO). In an aspect, forming the magnetic tunnel junction layer having the edge region with a chemical damage may form the chemical damage to include an oxidation material. In a related aspect, the transforming may include a de-oxidation.

In an aspect, the de-oxidation may include forming an insulating MTJ-edge-restoration-assist layer to surround the oxidation material. The insulating MTJ-edge-restoration assist layer may contain an element having an electronegativity not less than an electronegativity of Fe and Co, and not greater than an electronegativity of Mg.

In another aspect, the de-oxidation may comprise pulling oxygen from the oxidation material without pulling oxygen from the magnesium oxide of the tunnel barrier layer, and the pulling oxygen may comprise forming an insulating MTJ-edge-restoration-assist layer to surround the oxidation material, having an electronegativity not less than an electronegativity of Fe and Co, and not greater than an electronegativity of Mg.

In an aspect, a MTJ-edge-protection layer may be formed to surround the insulating MTJ-edge-restoration assist layer. The MTJ-edge-protection layer may comprise a dense insulating material and may contain an element having an electronegativity larger than an electronegativity of the insulating MTJ-edge-restoration-assist layer.

One or more exemplary embodiments may include a magnetic tunnel junction structure having an MTJ layer having a peripheral edge, and an insulating MTJ-edge-restoration-assist layer surrounding the peripheral edge of the MTJ layer, the insulating MTJ-edge-restoration-assist layer containing an element having an electronegativity not less than an electronegativity of Fe and Co, and not greater than an electronegativity of Mg. The MTJ layer, in an aspect, may include a portion or region proximal to the peripheral edge formed by an oxidation or nitridation, or both, followed by a de-oxidation or de-nitridation, or both.

In an aspect, a magnetic tunnel junction structure according to one or more exemplary embodiments may further include an MTJ-edge-protection layer surrounding the insulating MTJ-edge-restoration-assist layer.

One more exemplary embodiments may include a computer readable tangible medium storing instructions executable by a computer that, when executed by the computer, cause the computer to perform a method of repairing or reducing chemical damage of an edge region of a magnetic tunnel junction layer. In an aspect, the instructions when executed cause the computer to form the magnetic tunnel junction layer having the edge region with a chemical damage, which may include an oxidation material or a nitridation material, and instructions that when executed cause the computer to transform the oxidation or the nitridation material to form a chemically restored edge region. In an aspect, the transforming may include a de-oxidation, a de-nitridation, or de-water, or any combination thereof.

One or more exemplary embodiments may provide methods for fabricating a magnetic tunnel junction (MTJ) device, and example methods may include providing a multi-layer structure including a substrate, a ferromagnetic pinned layer above the substrate, a tunnel barrier layer above the ferromagnetic pinned layer, a ferromagnetic free layer above the tunnel barrier layer, and a top conducting layer above the ferromagnetic free layer. Methods may include, in an aspect, etching the multi-layer structure to form a pillar including a portion of the ferromagnetic free layer having a chemically damaged peripheral edge region, the chemically damaged peripheral edge region having an oxidation material or a nitridation material. In other aspects, transforming the chemically damaged peripheral edge region may include forming a chemically restored peripheral edge region, and the transforming according the aspects may include a de-oxidation, a de-nitridation, or de-water, or any combination thereof. In another aspect, methods may include forming an insulating MTJ-edge-restoration-assist layer to surround the chemically restored peripheral edge region of the ferromagnetic free layer of the pillar.

One more exemplary embodiments may include an apparatus for repairing or reducing chemical damage to an edge region of a magnetic tunnel junction layer, and an example apparatus may include means for forming the magnetic tunnel junction layer having the edge region, wherein the means for forming is configured to form the edge region with an oxidation material or a nitridation material, and means for transforming the oxidation material or the nitridation material to a chemically restored edge region.

In an aspect, the means for transforming may be configured to perform a de-oxidation, a de-nitridation, or de-water, or any combination thereof.

### BRIEF DESCRIPTION OF THE DRAWINGS

The accompanying drawings found in the attachments are presented to aid in the description of embodiments of the invention and are provided solely for illustration of the embodiments and not limitation thereof.

FIG. 1 shows a cutaway front projection view of a conventional multi-layer MTJ device.

FIG. 2 is a planar view, from the FIG. 1 projection 2-2, of one ferromagnetic layer of the FIG. 1 conventional multi-layer MTJ device, representing a peripheral edge region with “ideal” chemical/ferromagnetic structure.

FIG. 3A is the FIG. 1 cutaway front projection view, showing by superposed diagram one representative example of a kind of chemically damaged peripheral region, formed through conventional fabrication of ferromagnetic layers.

FIG. 3B shows a mapping of the FIG. 3A superposed diagram to the FIG. 2 planar view of the one ferromagnetic layer.

FIG. 4 shows by superposed diagram one representative example of the kind of chemically damaged peripheral region diagrammed by FIG. 3A, as it remains subsequent to conventional protective layer techniques.

FIG. 5A is a cut-away projection view of one example multi-layer edge-restored/edge-protected MTJ device according to one exemplary embodiment, including an edge-restored/edge-protected layer aspect, formed by processes in accordance with one or more exemplary embodiments.

FIG. 5B is a cut-away projection view of the FIG. 4A edge-restored/edge-protected MTJ device of FIG. 4A, from the FIG. 4A projection 4-4.

FIGS. 6A-6F show a snapshot sequence of cross-sectional diagrams, describing example structures and example processes providing edge-restoration and edge-protection for MTJ layers in an aspect of one or more exemplary embodiments.

FIG. 7 shows one flow chart diagram of operations further to various aspects providing edge-restoration and edge-protection of layers in and of MTJ devices according to one or more exemplary embodiments.

FIG. 8 shows one system diagram of one wireless communication system having, supporting, integrating and/or employing MTJ elements, and processes of fabricating MTJ elements, according to aspects of various exemplary embodiments.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted on as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields, electron spins particles, electrospins, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To illustrate this interchangeability of hardware and software, various illustrative components, blocks, modules, circuits, and steps are described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

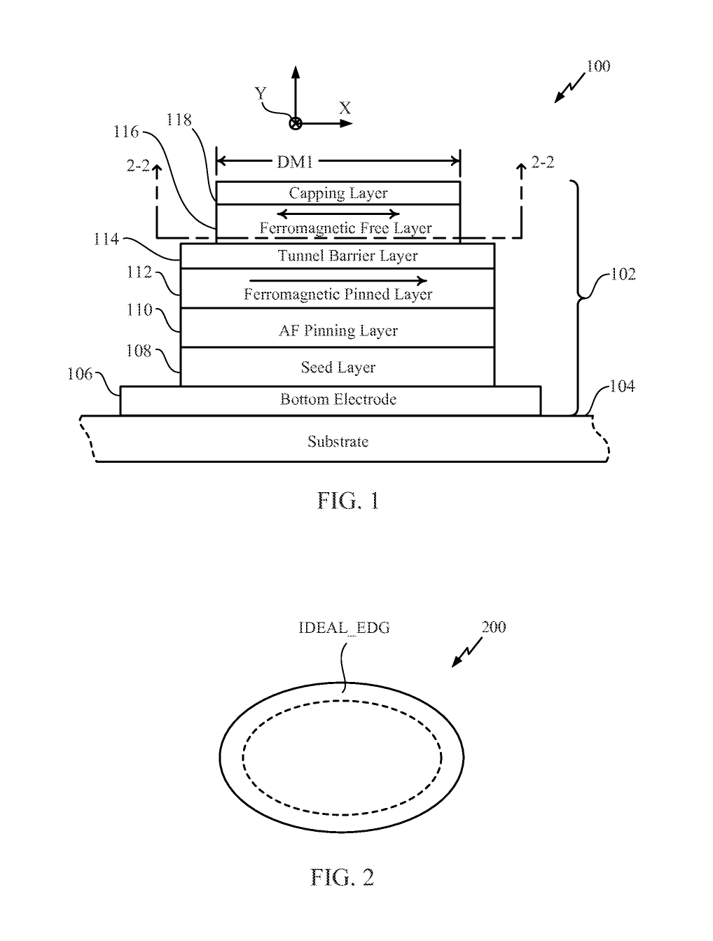

FIG. 1 shows a cutaway front view of a multi-layer MTJ device 100 formed in a conventional fabrication of MTJ devices. The FIG. 1 multi-layer MTJ device 100 is shown in simplified form omitting, for example, read/write access and other circuitry for which description is not necessary for persons of ordinary skill in the art, having view of this disclosure, to understand the inventive concepts or practice according to one or more of the exemplary embodiments. It will also be understood that “device,” as used in the term “multi-layer MTJ device” 100, imports no meaning. For example, the FIG. 1 multi-layer MTJ device 100 may be a fully fabricated device, or may be an “in-process” structure, i.e., portions (not separately labeled) of its depicted structure may be removed or modified by subsequent processing, in accordance with conventional MTJ fabrication techniques.

Referring to FIG. 1, the multi-layer MTJ device 100 can include what is termed in this disclosure as an MTJ pillar 102, on a conventional MTJ substrate 104. Described in order, starting at the first position above the MTJ substrate 104, the MTJ pillar 102 can include bottom electrode 106, seed layer 108, anti-ferromagnetic (AF) pinning layer 110, a ferromagnetic pinned layer 112 as one magnetic tunnel junction layer, a tunnel barrier layer 114, ferromagnetic free layer 116 as another magnetic tunnel junction layer and a top conducting, or capping layer 118. Each of the layers extends in the FIG. 1 X-Y plane, with X being normal to the plane of the figure, and Y being the horizontal axis of the figure.

As will be appreciated by persons of ordinary skill in the art from reading this disclosure, the FIG. 1 the MTJ pillar 102 includes certain features found in a wide range of MTJ devices. It will also be understood by such persons that conventional MTJ fabrication techniques of the MTJ pillar 102, and of comparable structure found in the wide range of MTJ devices, may include starting with a wider (in the X-Y plane) multi-layer structure having the FIG. 1 cross section of layers, and then removing material (for example by etching) to obtain the MTJ pillar 102 as a remaining structure.

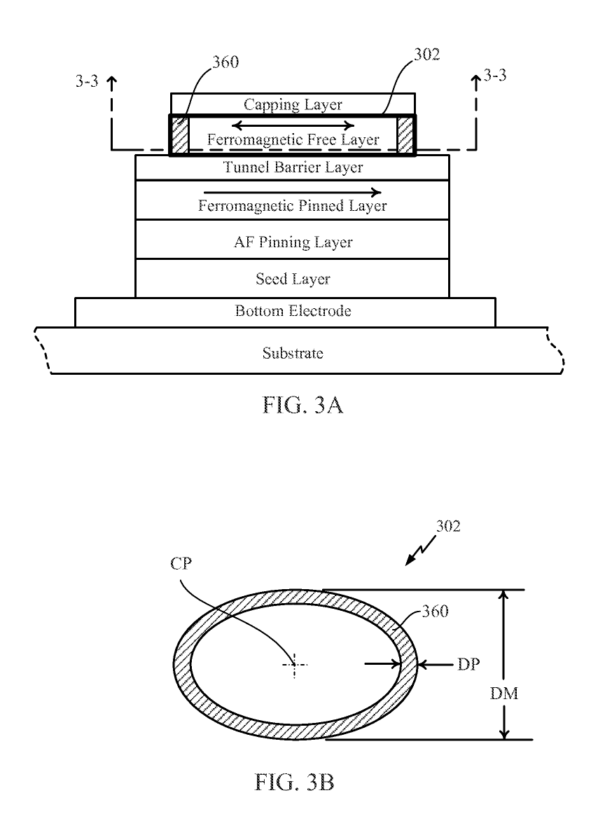

FIG. 2 is a planar view, from the FIG. 1 projection 2-2, of one hypothetical ideal structure ferromagnetic free layer 200 that may implement the ferromagnetic free layer 116. The hypothetical ideal structure ferromagnetic free layer 200 is hereinafter referenced, for brevity, as the “hypothetical ideal SF layer 200.” The hypothetical ideal SF layer 200 assumes a peripheral edge region, artificially demarcated by a superposed diagram as IDEAL_EDG, having an “ideal” chemical/ferromagnetic structure, meaning its material is the same as the remaining regions of the hypothetical ideal SF layer 200, i.e., the regions bounded by IDEAL_EDG. It will be understood that relative to the concepts of the exemplary embodiments, the term “ideal” means a uniformity of structure, without chemical damage to certain regions. The term “ideal” is not intended to characterize any other particular aspect of the hypothetical ideal SF layer 200. As illustration, one example hypothetical ideal SF layer 200 may be formed of a first ferromagnetic material, having a first set of ferromagnetic parameter values, and another example hypothetical ideal SF layer 200 may be formed of a second ferromagnetic material, having a second set of ferromagnetic parameter values.

Referring still to FIG. 2, for convenience the region of the hypothetical ideal SF layer 200 inside the IDEAL_EDG will be termed its “main region.” The IDEAL_EDG is assumed to result from hypothetical removal of material from a multi-layer MTJ starting structure to obtain the MTJ pillar 102 as a remaining structure—without damage to any remaining structure, e.g., chemical reactions due to etching energy. The IDEAL_EDG is therefore not a delineation of any structural change. On the contrary, according to the hypothetical ideal SF layer 200, the structure (i.e., chemical make-up and ferromagnetic property) is the same irrespective of location relative to IDEAL_EDG. The IDEAL_EDG is therefore only a reference for comparison to structure at similarly located regions in actually fabricated structures of the FIG. 1 ferromagnetic free layer 116, as described in greater detail at later sections.

As previously described in this disclosure, the IDEAL_EDG of the FIG. 2 hypothetical ideal SF layer 200 assumes hypothetical removal of material from a multi-layer MTJ starting structure to obtain the MTJ pillar 102 as a remaining structure—without application of energy and without effecting any chemical reaction. However, known etching techniques for removing material from a multi-layer MTJ starting structure, to obtain the MTJ pillar 102 as a remaining structure, applies energy. The energy combined with the processing environment can effect undesired chemical reactions at the peripheral edge of various of the MTJ pillar 102 layers, for example at the peripheral edge of the ferromagnetic free layer 116. Examples of such chemical damage include oxidation forming an oxidation material, nitridation forming a nitridation material, or a combination of oxidation and nitridation.

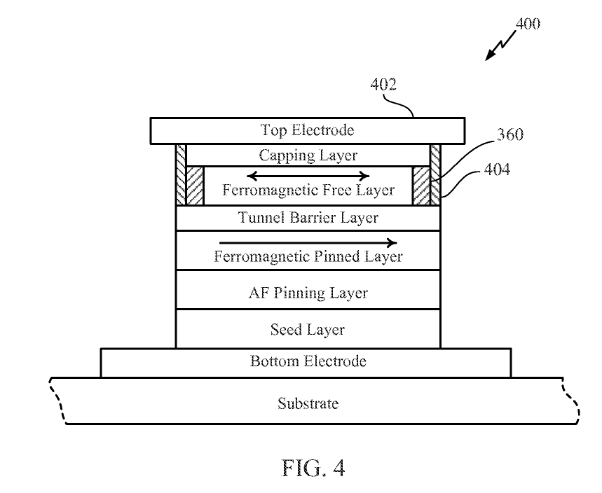

FIG. 3A shows, as a diagram superposed on the FIG. 1 cutaway front projection view, a damaged peripheral edge ferromagnetic free layer 302 comprising the ferromagnetic free layer 116 having a chemically damaged peripheral region 360, representing one general distribution of such chemical damage that can arise from conventional etching techniques.

FIG. 3B shows the FIG. 3A damaged peripheral edge ferromagnetic free layer 302 viewed from the FIG. 3A projection 3-3. FIG. 3B shows the damaged peripheral edge ferromagnetic free layer 302 having an elliptical cross-section, but labels only the minor diameter, shown as “DM.” The aspect ratio of the major diameter (shown, but not labeled) to DM may be anywhere in the range (which may include unity) formed by the conventional techniques.

Referring to FIGS. 3A and 3B, the chemically damaged peripheral region 360 can represent oxidation, nitridation or both, of the material forming the layer (not explicitly shown) of the MTJ multi-layer starting structure from which the damaged peripheral edge ferromagnetic free layer 302 was formed. The oxidation, nitridation, or both, can arise from, for example, nitrogen or oxygen, or both, introduced during the etching processes. The specific chemical make-up of the oxidation, nitridation, or both that formed the chemically damaged peripheral region 360 depends, at least in part, on the chemical make-up of the MTJ multi-layer starting structure from which the damaged peripheral edge ferromagnetic free layer 302 was formed.

For example, in an aspect the damaged peripheral edge ferromagnetic free layer 302 may be formed of i.e., etched from a layer of a soft ferromagnetic material, for example iron (Fe). Nitridation of an Fe ferromagnetic can produce hard magnetic materials, for example FeN. A hard magnetic FeN composition of the chemically damaged peripheral region 360 may have untoward effects in the performance characteristics of the damaged peripheral edge ferromagnetic free layer 302 when the fabrication is complete and it is part of an operative MTJ device. Example of untoward effects can be, for example, any one of, or any combination of large magnetic saturation (Ms), large offset magnetic field (Hoff), lower exchange constant, reduced tunnel magnetoresistance (TMR), and/or degradation of the R-H loop.

Continuing to refer to FIGS. 3A-3B, the chemically damaged peripheral region 360 can begin at, or substantially coincident with, the outer edge (shown not separately labeled) and extend to an average depth DP measured in a radial direction to a geometric center CP. It will be understood that the FIG. 3B graphic representation of the ratio average depth DP relative to the diameter DM is for visibility in the figures and is not intended to represent a numerical value of the ratio of DP to DM.

It is notable that in conventional fabrication of MTJ devices, after etching to form pillars such as the FIG. 1 MTJ pillar 102, one or more layers can be applied. It is further notable that in instances in conventional fabrication in which the etching forms damage regions, as shown by the FIG. 3A-3B chemically damaged peripheral region 360, that the one or more layers may be applied on such damaged peripheral regions. Such layers can be referred to in the conventional MTJ fabrication art as “protective layers.”

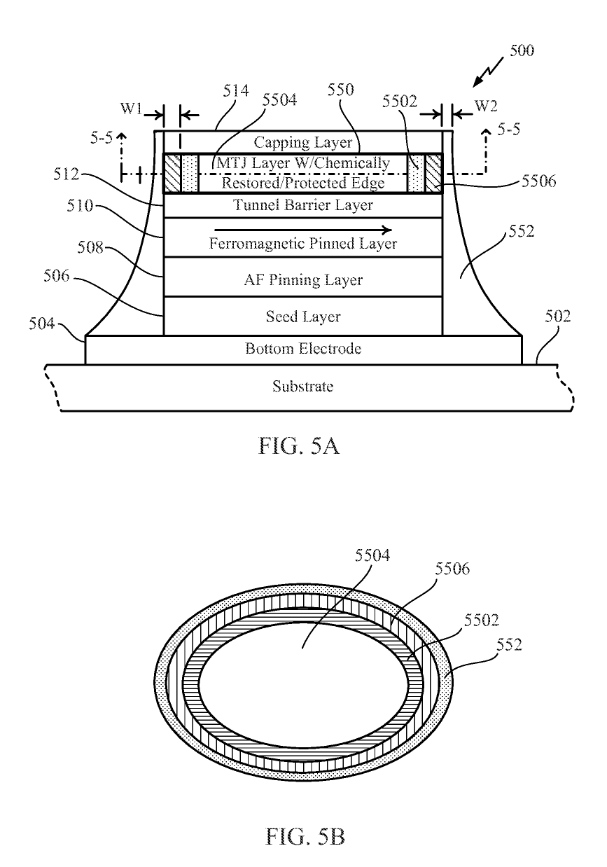

FIG. 4 shows a FIG. 1 multi-layer MTJ device 400 having a top electrode 402 and, as shown by superposed diagram, a prior art “protective layer” 404 formed on the FIG. 3A-3B example of the multi-layer MTJ device 100, having the damaged peripheral edge ferromagnetic free layer 302, with its chemically damaged peripheral region 360.

In one embodiment, a restoration of damaged regions of the kind exemplified by the FIG. 3A-3B chemically damaged peripheral region 360 can be provided and, in an aspect, the restoration can transform such damaged regions to a chemically restored edge.

In an aspect, an insulating MTJ-edge-restoration-assist layer may be formed on the chemically restored MTJ edge. As described in greater detail at later sections, exemplary embodiments having, in combination, the chemically restored MTJ edge formed on insulating MTJ-edge-restoration-assist layer, can provide feature and benefits that include, but are not limited to, advancement in protection against oxide and/or nitride damage.

In an aspect, described in greater detail at later sections, an MTJ-edge-protection layer can be formed on the insulating MTJ-edge-restoration-assist layer formed on the chemically restored MTJ edge.

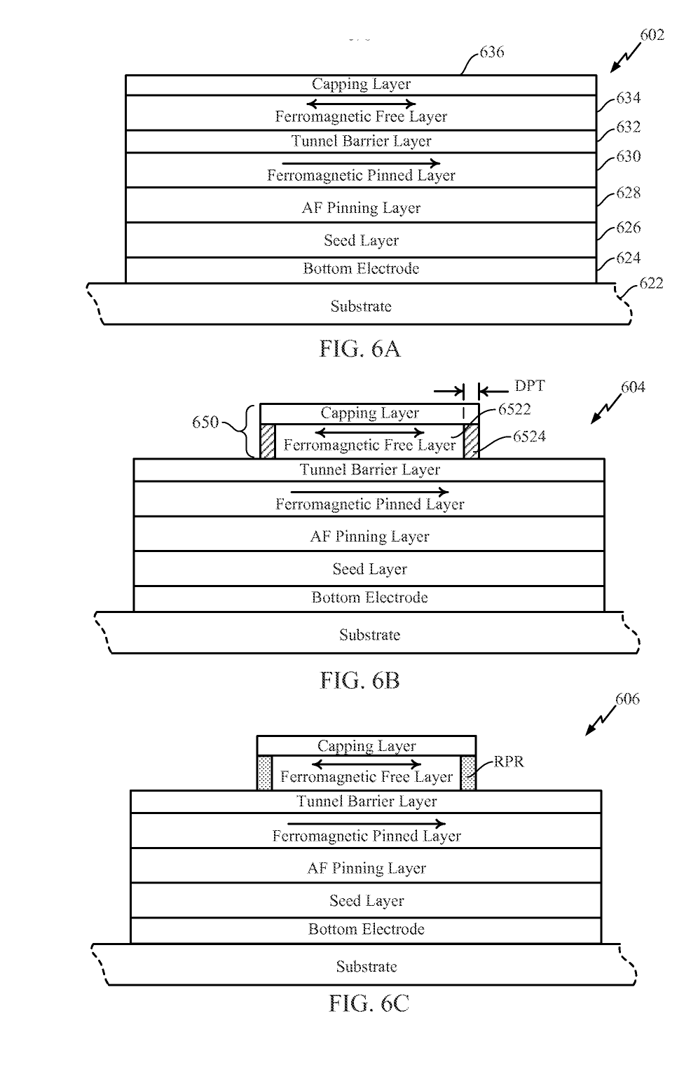

FIG. 5A shows a cut-away projection view of one edge-restored/edge-protected MTJ device 500 having structure according to, and formed by various operations in accordance with, one or more exemplary embodiments. FIG. 5B is a cut-away view of the FIG. 5A edge-restored/edge-protected MTJ device 500 seen from the FIG. 5A projection 5-5. It will be understood that the term “edge restored/edge protected” is used in this description only for convenience in referencing the example structure shown by FIG. 5A-5B, and is not intended to import any additional meaning.

The example structure shown in FIG. 5A-5B for the edge-restored/edge-protected MTJ device 500 is chosen to be an adoption of the general stacking configuration of the FIG. 1 multi-layer device 100. It will be understood that this example magnetic tunnel junction structure is used to assist in focusing on novel aspects, without requiring introduction and description of additional structures not particular to the exemplary embodiments. As will be readily appreciated by persons of ordinary skill in the art, upon reading this disclosure, practices in accordance with various exemplary embodiments are not limited to structures adopting the general stacking configuration of the FIG. 1 multi-layer MTJ device 100.

Referring to FIG. 5A, edge-restored/edge-protected MTJ device 500 can include an MTJ substrate 502, and a bottom electrode 504 disposed on the MTJ substrate 502. The MTJ substrate 502, and bottom electrode 504 can be structured, and formed in accordance with conventional MTJ techniques. On the bottom electrode 504 is a multi-layer pillar structure (shown but not separately labeled) having, starting at the lower position, seed layer 506, AF pinning layer 508, ferromagnetic pinned layer 510, tunnel barrier layer 512, chemically restored/protected edge MTJ layer 550 and top conducting, or capping layer 514.

Referring still to FIG. 5A, the chemically restored/protected edge MTJ layer 550 can be a ferromagnetic free layer with respect to its function. In an aspect, the chemically restored/protected edge MTJ layer 550 can include chemically restored/protected edge MTJ layer main region 5504 and, in a further aspect, the chemically restored/protected edge MTJ layer main region 5504 is surrounded by chemically restored peripheral region 5502. In an aspect, the chemically restored peripheral region 5502 can be a transformation of a chemically damaged peripheral region (not visible on FIGS. 5A-5B) that may be comparable, in its mechanism of formation and its structure, to the chemically damaged peripheral region 360 described in reference to FIGS. 3A-3B. Processes in accordance with various exemplary embodiments for forming chemically restored peripheral region 5502 are described in greater detail at later sections.

Continuing to refer to FIG. 5A, in an aspect MTJ-edge-restoration-assist layer 5506 is formed to surround chemically restored peripheral region 5502. Further to this aspect, the chemically restored peripheral region 5502 surrounded by the MTJ-edge-restoration-assist layer 5506 may be alternatively referred to as “protected edge region” or “protected chemically restored peripheral edge region” 5502. Also related to this aspect, the MTJ-edge-restoration-assist layer 5506 can be formed to have a width (or thickness) of W1, in the X direction, as described in greater detail at later sections.

It will be understood that, in an aspect, the transformation forming the chemically restored peripheral region 5502 is performed prior to the process of forming the MTJ-edge-restoration-assist layer 5506. Also according to the aspect, the processes of fabrication can be controlled to avoid damage to the chemically restored peripheral region 5502 in the interval between its formation and the forming of the forming the MTJ-edge-restoration-assist layer 5506. Aspects with respect to materials and properties of materials forming the MTJ-edge-restoration-assist layer 5506 are described in greater detail at later sections.

Referring still to FIG. 5A, in an aspect, NM-edge-protection layer 552 is formed to surround MTJ-edge-restoration-assist layer 5506. Further to the aspect, the MTJ-edge protection layer 552 can be formed to have a width (or thickness) of W2 in the region surrounding the MTJ-edge-restoration-assist layer 5506. Aspects with respect to materials and properties of materials forming the MTJ-edge-protection layer 552 are described in greater detail at later sections. In a further aspect, the MTJ-edge-protection layer 552 may be formed to surround not only the MTJ-edge-restoration-assist layer 5506 of the chemically restored/protected edge MTJ layer 550, but to also surround the entire multi-layer pillar structure, i.e., the seed layer 506, AF pinning layer 508, ferromagnetic pinned layer 510, tunnel barrier layer 512, chemically restored/protected edge MTJ layer 550 and capping layer 514.

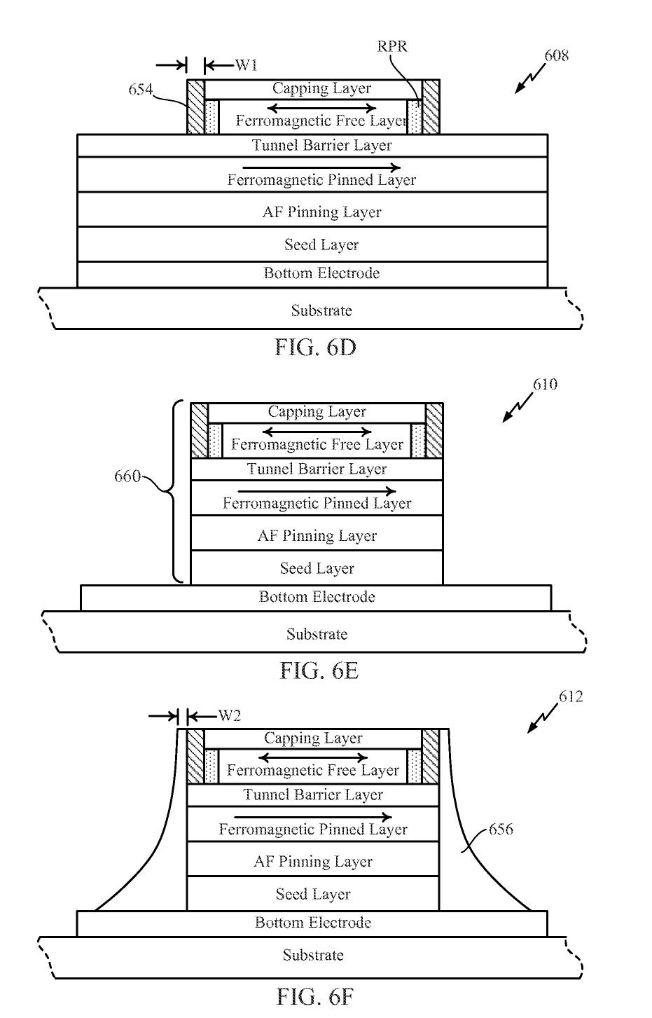

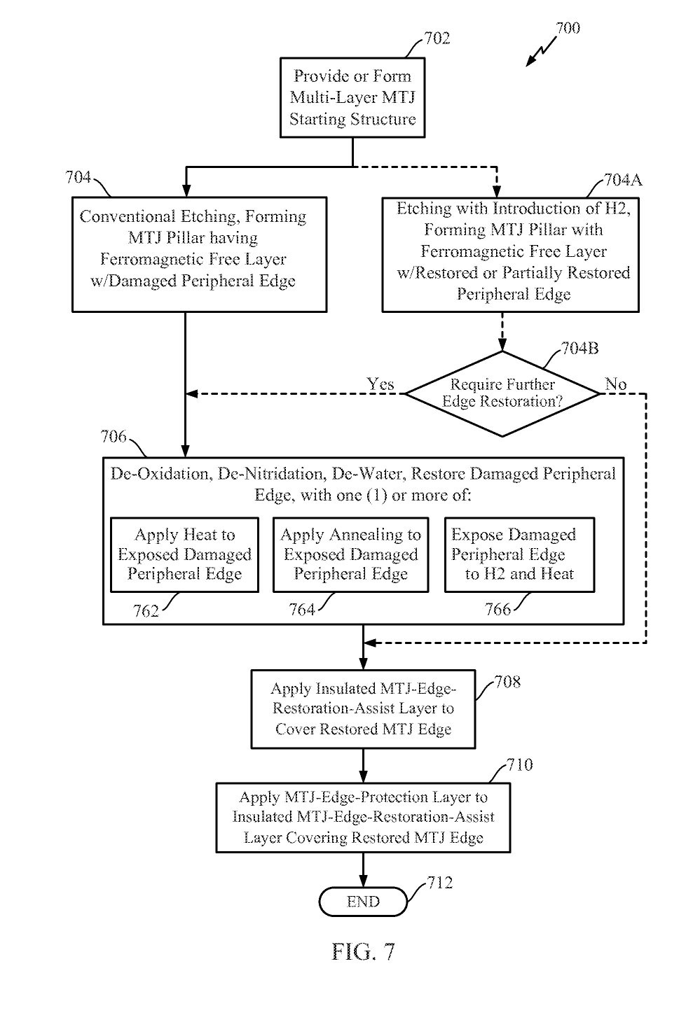

FIGS. 6A-6F show a sequence of structural formations that may be intermediate structures formed in a process according to an aspect of one or more exemplary embodiments, examples of which are described in greater detail in reference to FIG. 7.

FIG. 6A shows an example MTJ multi-layer starting structure 602 having, listed in their depicted stacking order beginning with MTJ substrate 622, bottom electrode 624, seed layer 626, AF pinning layer 628, ferromagnetic pinned layer 630, tunnel barrier layer 632, ferromagnetic free layer 634, and top conducting, or capping layer 636. In an aspect, the ferromagnetic free layer 634 can be CoFeB or CoFe. In another aspect, the tunnel barrier layer 632 can be MgO. These example materials of the ferromagnetic free layer 634, i.e., CoFeB or CoFe and the tunnel barrier layer 632, i.e., MgO, in accordance with these aspects may in turn relate to another aspect, described in greater detail at later sections, pertaining to later-formed layer (not shown in FIG. 6A) corresponding generally to the FIG. 5A MTJ-edge-restoration-assist layer 5506. In this further aspect, the MTJ-edge-restoration-assist layer (not shown in FIG. 6A) layer may be formed with a material having an electron negativity having a particular relation to the electron negativity of Mg, Fe and Co. According to this aspect, as will be described in greater detail at later sections, this particular relation of electronegativity can provide for pulling oxygen from chemically damaged regions (not shown in FIG. 6A) of structure formed from the ferromagnetic free layer 634 without pulling the oxygen from the MgO forming the tunnel barrier layer 632.

Referring still to FIG. 6A, in an example process according to one exemplary embodiment, conventional etching can be performed on the FIG. 6A MTJ multi-layer starting structure 602, for example down to the tunnel barrier layer 632, to form the FIG. 6B in-process structure 604 having in-process MTJ pillar 650. In an aspect, conventional etching may be used to form the in-process MTJ pillar 650, and can be applied to form an in-process ferromagnetic free layer, shown labeled according to its constituent parts, which are MTJ free layer main region 6522 and MTJ free layer damaged peripheral edge region 6524, having an average depth in the X direction of DPT. The mechanism of forming, and the chemical make-up of the MTJ free layer damaged peripheral edge region 6524 can be, for example, one or more of the mechanisms for forming, and chemical make-up of the chemically damaged peripheral region 360 described in reference to FIGS. 3A-3B.

Referring to FIG. 6C, in an aspect a de-oxidation, de-nitridation, or both are performed to transform the MTJ free layer damaged peripheral edge region 6524 to the MTJ free layer restored peripheral edge region RPR of the in-process structure 606. In a further aspect, transforming the MTJ free layer damaged peripheral edge region 6524 to the MTJ free layer restored peripheral edge region RPR of the in-process structure 606 may be a de-water process, a de-oxidation, or de-nitridation, or any combination thereof. Aspects of de-oxidation, de-nitridation and other processes related to the transforming are described in greater detail at later sections. As illustration, the de-oxidation, de-nitridation, or de-water, or any combination thereof, can include raising the temperature of the MTJ free layer damaged peripheral edge region 6524, and applying other processes, to draw out nitrogen, oxygen or both. As will be appreciated, in accordance exemplary embodiments, these processes can transform the MTJ free layer damaged peripheral edge region 6524 back to the ferromagnetic material of the MTJ free layer main region 6522, i.e., to the material of the ferromagnetic free layer 634. In one example, the MTJ free layer restored peripheral edge region RPR of the in-process structure 606 can become, at a later processing, the FIG. 5A chemically restored peripheral region 5502.

It will be understood that, in an aspect, the restoration transforming the MTJ free layer damaged peripheral edge region 6524 to its original ferromagnetic material is preferably performed when the MTJ free layer damaged peripheral edge region 6524 is in an exposed state. Stated differently, de-oxidation, de-nitridation, or both, that pull the nitrogen or oxygen, or both from the MTJ free layer damaged peripheral edge region 6524 are preferably performed on the FIG. 6B in-process structure 604, or a later in-process structure, prior to forming a layer impeding the drawing out of nitrogen or oxygen. This aspect, as will be appreciated by persons of ordinary skill having view of this disclosure, can significantly increase the quality of the transformation of the MTJ free layer damaged peripheral edge region 6524 to the MTJ free layer restored peripheral edge region RPR.

Referring to FIG. 6D, in-process structure 608 illustrates one example of forming, in an aspect, an insulating MTJ-edge-restoration-assist layer 654 to surround the MTJ free layer restored peripheral edge region RPR after transforming the MTJ free layer damaged peripheral edge region 6524 to the restored peripheral edge region RPR. Referring to FIG. 5A, the insulating MTJ-edge-restoration-assist layer 654 can become, at a later processing, the insulating MTJ-edge-restoration-assist layer 5506.

Referring still to FIG. 6D, as previously described, in an aspect the tunnel barrier layer can be formed of MgO. In a related aspect, the insulating MTJ-edge-restoration-assist layer 654 can contain an element having an electronegativity smaller than an electronegativity of Fe and Co, yet stronger than an electronegativity of magnesium. In other words, according to this aspect, the element has an active chemical bond to oxygen and nitrogen not less than the active chemical bond of Co and Fe to oxygen and nitride, but weaker than the active chemical bond of Mg to oxygen and nitrogen. Examples are: Al₂O₃, MgO, HfO₂, TaO, TiO, etc., and AlN, Mg₃N₂, Mg₄N₃, HfN, SiN, and Si3N4, SiC, etc.

Referring to FIGS. 6C and 6D, in one aspect, the insulating MTJ-edge-restoration-assist layer 654, having an electronegativity in the described relation to that of Fe and Co of the ferromagnetic free layer 634 and that of Mg of the tunnel barrier layer 632, can be formed after forming the FIG. 6C in-process structure 606 as described. According to this aspect, further de-oxidation can pull remaining oxygen (if any) from the MTJ free layer restored peripheral edge region RPR without pulling the oxygen from the MgO forming the tunnel barrier layer 632.

Referring to FIG. 6D, in another aspect, the insulating MTJ-edge-restoration-assist layer 654, having an electronegativity in the described relation to that of Fe and Co of the ferromagnetic free layer 634 and that of Mg of the tunnel barrier layer 632, can be formed on the FIG. 6B in-process structure 604. According to this aspect, the forming of the insulating MTJ-edge-restoration-assist layer 654 on the FIG. 6D in-process structure 604, having the described electronegativity in relation to that of Fe and Co (in the ferromagnetic free layer 634) and of Mg (in the tunnel barrier layer 632), can pull oxygen from the FIG. 6B MTJ free layer damaged peripheral edge region 6524, without pulling the oxygen from the MgO forming the tunnel barrier layer 632. This forming of the described insulating MTJ-edge-restoration-assist layer 654 on the FIG. 6D in-process structure 604 may therefore transform the FIG. 6B MTJ free layer damaged peripheral edge region 6524 into the MTJ free layer restored peripheral edge region RPR shown in FIG. 6D. In other words, according to this aspect, forming the MTJ free layer restored peripheral edge region RPR may be performed by, and therefore may be concurrent with, forming the insulating MTJ-edge-restoration-assist layer 654.

Referring to FIG. 6E, in-process structure 610 shows one example according to an aspect of etching, after forming the insulating MTJ-edge-restoration-assist layer 654 on the MTJ free layer restored peripheral edge region RPR, to extend the in-process MTJ pillar 650 to a near-complete MTJ pillar 660. The etching may be performed, for example, with conventional etching techniques.

Referring next to FIG. 6F, in-process structure 612 shows one example forming, in an aspect, of MTJ-edge-protection layer 656 to surround the insulating MTJ-edge-restoration-assist layer 654. The MTJ-edge-protection layer 656 may be, for example, the FIG. 5A insulating MTJ-edge-protection layer 552 having the width W2. In an aspect the MIT edge-protection layer 656 can be formed of a dense insulating material, such as Al₂O₃. In a further aspect, the MTJ-edge-protection layer 656 can contain an element having an electronegativity larger than that of the insulating MTJ-edge-restoration-assist layer 654. Among various benefits of this aspect is that the insulating MTJ-edge-protection layer 656 can serve as a protection layer to prevent further MTJ edge damage due, for example, to oxygen and/or nitrogen during SiN low pressure chemical vapor deposition (LPCVD) processes.

The above-described operations performed a two (or more) step etching and restoration, namely a first etching to a depth only forming the ferromagnetic free layer 634 with its MTJ free layer damaged peripheral edge region 6524, followed by forming the MTJ free layer restored peripheral edge region RPR, then forming the insulating MTJ-edge-restoration-assist layer 654 to cover the MTJ free layer restored peripheral edge region RPR. Further etching then formed the remainder of the in-process MTJ pillar 650. Various exemplary embodiments include a single step etching, or at least a single step to a depth sufficient to form both the ferromagnetic free layer 634 and the ferromagnetic pinned layer 630, followed by above-described restoration on both. Such a restoration according to exemplary embodiments can form a region such as the MTJ free layer restored peripheral edge region RPR in both the ferromagnetic free layer 634 and the ferromagnetic pinned layer 630, followed by surrounding or covering these with a protecting layer such as the insulating MTJ-edge-restoration-assist layer 654.

FIG. 7 shows one flow chart diagram of one process 700 further to various aspects of edge-restoration and edge-protection of layers of MTJ devices according to one or more exemplary embodiments.

Referring to FIG. 7, one example operation of process 700 can begin at 702 with providing or forming a multi-layer MTJ starting structure, such as the FIG. 6A MTJ multi-layer starting structure 602, or any other multi-layer starting structure from which MTJ devices can be etched. In an aspect, the NM starting structure can include a ferromagnetic layer, such as the FIG. 6A ferromagnetic free layer 634, for of CoFeB or CoFe.

Referring still to FIG. 7, in one example operation of process 700, after being provided with or forming the multi-layer MTJ starting structure at 702, conventional etching can be performed at 704 to obtain an in-process MTJ pillar having a ferromagnetic free layer. Due to conventional etching, the ferromagnetic free layer may have, as described above, the FIG. 6B MTJ free layer main region 6522 and MTJ free layer damaged peripheral edge region 6524. The in-process pillar may have this ferromagnetic free layer as a lower layer, and may have an upper portion (shown but not separately numbered) having, for example, the capping layer 636.

Before describing acts of process 700 subsequent to the etching and related forming of MTJ free layer damaged peripheral edge regions at 704, it is noted again that an aspect of one or more exemplary embodiments includes maintaining these regions exposed until the restoration at 706, described below.

Continuing to refer to FIG. 7, in one example operation of process 700, after conventional etching 704 to obtain the desired MTJ layers (and their corresponding damaged peripheral edge regions), the process can go to 706 to restore these MTJ free layer damaged peripheral edge region(s) back to their original starting state. For example, in one operation of process 700, after 704 formed MTJ free layer damaged peripheral edge region(s) 6524, the process can go to 706 and restore these back to their original state, i.e., to the chemical state of the ferromagnetic free layer 634 formed, e.g., of CoFeB or CoFe.

As shown in FIG. 7, in one example operation of process 700 the restoration at 706 can include applying one of, or any combination of any of the following operations on the exposed damaged peripheral edge regions formed by the etching at 704; a heating at 762; an annealing at 764 and/or an application or exposure of H₂ to the exposed damaged peripheral edge regions at 766, with or without being at an elevated temperature. Heating at 762 can include raising the temperature of the exposed damaged peripheral edge regions above a temperature at which the undesired oxides or nitrides decompose. Assuming for example that exposed damaged peripheral edge regions formed by the etching at 704 include FeN, the heating at 762 can include raising the temperature to approximately 200 degrees C. (200° C.), at which FeN decomposes. An annealing at 764 can include a particular temperature cycling of heating to specific temperature, and cooling at given slow rate, to assist oxygen and nitrogen escaping from the FIG. 3B chemically damaged peripheral region 360.

Referring to FIG. 7, in one example operation of process 700, after restoring at 706 of the damaged peripheral edge regions to their original state (e.g., the FIG. 6C region RPR), an MTJ-edge-restoration-assist layer may be formed at 708 to surround the restored peripheral edge. Referring to FIG. 6D, forming the insulating MTJ-edge-restoration-assist layer 654 may be one example of a forming an MTJ-edge-restoration-assist layer at 708. As previously described, the ferromagnetic free layer of the multi-layer MTJ starting structure (not specifically shown in FIG. 7) provided at 702 may be formed of CoFeB or CoF. As described in reference to FIGS. 5A, 5B and 6A-6F, the tunnel barrier layer (not specifically shown in FIG. 7) of the multi-layer MTJ starting structure provided at 702 may be formed of MgO.

Referring to FIG. 7, in an aspect the insulating MTJ-edge-restoration-assist layer formed at 708 may contain an element having an electronegativity smaller than an electronegativity of Fe and Co, yet stronger than an electronegativity of magnesium. The element therefore has an active chemical bond to oxygen and nitrogen not less than the active chemical bond of Co and Fe to oxygen and nitride, but weaker than the active chemical bond of Mg to oxygen and nitrogen. Examples are: Al₂O₃, MgO, HfO₂, TaO, TiO, etc., and AlN, Mg₃N₂, Mg₄N₃, HfN, SiN, and Si3N4, SiC, etc.

Continuing to refer to FIG. 7, in one example operation of process 700, the forming at 708 of the insulating MTJ-edge-restoration-assist layer having an electronegativity in the described relation to that of Fe and Co of the ferromagnetic free layer and Mg of the tunnel barrier layer provided at 702, can be performed on the structure resulting from the restoring transforming at 706. Referring to FIGS. 6C, 6D and 7, one example of such a forming at 708 may be forming the insulating MTJ-edge-restoration-assist layer 654 to surround the MTJ free layer restored peripheral region RPR. As previously described, an insulating MTJ-edge-restoration-assist layer structured and formed in accordance with this aspect may pull remaining oxygen (if any) from the restored peripheral edge region formed at 706, without pulling the oxygen from the MgO forming the tunnel barrier layer of the multi-layer MTJ starting structure provided at 702.

With continuing reference to FIG. 7, in another aspect, assuming the above-described relation of the electronegativity of the element in the insulating MTJ-edge-restoration assist layer with that of Fe and Co of the ferromagnetic free layer and Mg of the tunnel barrier layer provided at 702, the forming at 708 may be merged with the restoring at 706. More particularly, forming at 708 of the insulating MTJ-edge-restoration assist layer with an element of electronegativity relative to that of Fe in the ferromagnetic free layer and Mg in the tunnel barrier layer as described can concurrently perform blocks 706 and 708. It can perform the transforming at 706 because of pulling oxygen from (i.e., de-oxidize) the chemically damaged (i.e., oxidized) MTJ free layer damaged peripheral edge region formed at 704, notably without pulling the oxygen from the MgO of the tunnel barrier layer. As can be appreciated, this can transform the damaged peripheral edge region to its original form. At the same time, it performs the forming at 708 of the insulating MTJ-edge-restoration assist layer.

In one example operation of process 700, after forming insulating MTJ-edge-restoration-assist layer at 708 on the restored regions formed at 706, the process can go to 710 and form an insulating MTJ-edge-protection-layer on the MTJ-edge-restoration-assist layer formed at 708. The insulating MTJ-edge-protection-layer, for example, may be formed as shown by the insulating MTJ-edge-protection-layer 656 shown at FIG. 6F. In an aspect the can be formed of a dense insulating material, such as Al₂O₃. In a further aspect, operations at 710 may form an Insulating MTJ-edge-protection-layer to contain an element whose electronegativity is larger than that of the insulating MTJ-edge-restoration-assist layer.

Referring to FIG. 7, in one example operation of process 700, after forming the insulating MTJ-edge-protection-layer at 700 the process can go to 712 where it ends.

Example operations of process 700 are described above as performing the restoring at 706 separate from the forming at 704. Further exemplary embodiments, however, may perform at least a portion of the transforming concurrently with the etching. Referring to FIG. 7, in an aspect such transforming may include an etching at 704A, instead of the conventional etching at 704, that comprises injecting an H₂ to react at a location of the etching, to perform a pulling of oxygen from the etching process. This can be characterized as preventing or reducing the oxidation, or as transforming the chemical damage, as it occurs, to an undamaged state. The pulling may occur because H₂ is more reactive to oxygen than magnetic materials such as Co and Fe. This, in turn, can significantly reduce the formation of the FIG. 6B MTJ free layer damaged peripheral edge region 6524. Accordingly, in a related aspect, a determination at 704B of whether the restoration at 706 needs to be performed may be included. If the answer at 704B is YES, the process may go to 706, if NO, the process may go to 708 for formation of the insulating MTJ-edge-restoration assist layer, as previously described.

Embodiments have been described assuming the ferromagnetic free layer, for example the in-process ferromagnetic free layer of FIG. 6B formed of the MTJ free layer damaged peripheral edge region 6524 and the MTJ free layer main region 6522, as being the layers for which edge restoration and edge maintenance in accordance with exemplary embodiments are desired. In one exemplary embodiment, the tunnel barrier layer, for example the FIG. 6A tunnel barrier layer 632, can be the layer for which edge restoration and edge maintenance in accordance with exemplary embodiments are desired. In an aspect, this can be provided by introducing H₂ gas. One example is that Mg(OH)₂ can be decomposed to MgO and H₂O at ˜30° ″C.

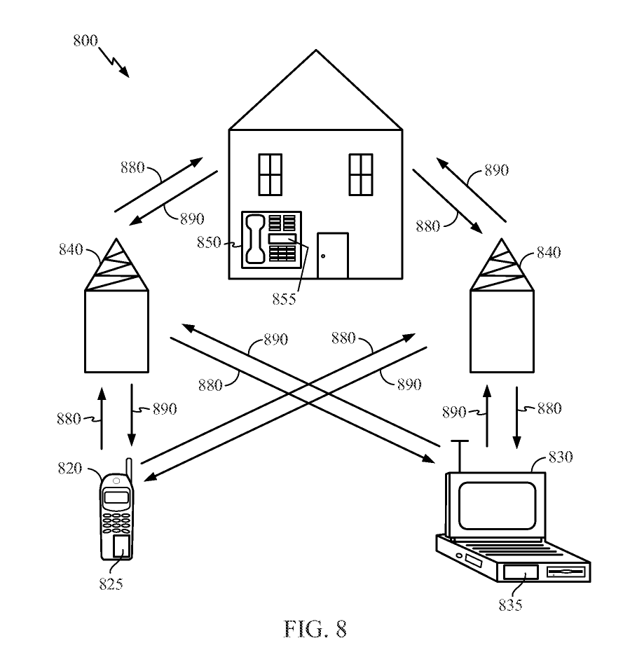

FIG. 8 illustrates an exemplary wireless communication system 800 in which one or more embodiments of the disclosure may be advantageously employed. For purposes of illustration, FIG. 8 shows three remote units 820, 830, and 850 and two base stations 840. It will be recognized that conventional wireless communication systems may have many more remote units and base stations. The remote units 820, 830, and 850 include integrated circuit or other semiconductor devices 825, 835 and 855 (including on-chip voltage regulators, as disclosed herein), which are among embodiments of the disclosure as discussed further below. FIG. 8 shows forward link signals 880 from the base stations 840 and the remote units 820, 830, and 850 and reverse link signals 890 from the remote units 820, 830, and 850 to the base stations 840.

In FIG. 8, the remote unit 820 is shown as a mobile telephone, the remote unit 830 is shown as a portable computer, and the remote unit 850 is shown as a fixed location remote unit in a wireless local loop system. For example, the remote units may be any one or combination of a mobile phone, hand-held personal communication device or personal communication system (PCS) unit, portable data unit such as a personal digital assistant or personal data assistant (either being referred to as a “PDA”), navigation device (such as GPS enabled devices), set top box, music player, video player, entertainment unit, fixed location data unit such as meter reading equipment, or any other device that stores or retrieves data or computer instructions, or any combination thereof. Although FIG. 8 illustrates remote units according to the teachings of the disclosure, the disclosure is not limited to these exemplary illustrated units. Embodiments of the disclosure may be suitably employed in any device that includes active integrated circuitry including memory and on-chip circuitry for test and characterization.

The foregoing disclosed devices and functionalities (such as the devices of FIGS. 5A-5B, sequence of structures shown by FIGS. 6A-6F, methods of FIG. 7, or any combination thereof) may be designed and configured into computer files (e.g., RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The semiconductor chips can be employed in electronic devices, such as described hereinabove.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for implementation. Accordingly, the invention is not limited to illustrated examples and any means for performing the functionality described herein are included in embodiments of the invention.

The foregoing disclosed devices and functionalities may be designed and configured into computer files (e.g., RTL, GDSII, GERBER, etc.) stored on computer readable media, for example a computer readable tangible medium having instructions executable on one or more processors. Some or all such files may be provided to fabrication handlers who fabricate devices based on such files. Resulting products include semiconductor wafers that are then cut into semiconductor die and packaged into a semiconductor chip. The chips are then employed in devices described above.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method for repairing or reducing chemical damage to an edge region of a magnetic tunnel junction layer, comprising:
forming the magnetic tunnel junction layer having the edge region with a chemical damage; and
transforming at least a portion of the edge region with the chemical damage to a chemically restored edge portion.

2. The method of claim 1, wherein the transforming includes raising a temperature of the edge region, while the edge region is exposed, to a temperature above 200 degrees C.

3. The method of claim 1, wherein the forming includes an etching, and wherein at least a portion of the transforming is performed concurrently with the etching, wherein said portion of the transforming comprises injecting H₂ in a manner to react at a location of the etching and pull an oxidation material formed by the etching.

4. The method of claim 1, wherein the transforming includes an annealing process.

5. The method of claim 1, wherein the transforming is performed until the chemically restored edge portion forms a chemically restored peripheral edge region of the magnetic tunnel junction layer.

6. The method of claim 5, further comprising transforming the chemically restored peripheral edge region into a chemically restored and protected edge region, wherein said transforming the chemically restored peripheral edge region includes forming an insulating MTJ-edge-restoration-assist layer to surround the chemically restored peripheral edge region.

7. The method of claim 6, further comprising forming an MTJ-edge-protection layer to surround the insulating MTJ-edge-restoration assist layer, wherein the MTJ-edge-protection layer comprises a dense insulating material.

8. The method of claim 6, wherein the forming forms the chemical damage to include an oxidation material,
wherein the magnetic tunnel junction layer is arranged facing a tunnel barrier layer having magnesium oxide (MgO),
wherein the magnetic tunnel junction layer includes iron (Fe), cobalt (Co), or both, and
wherein the insulating MTJ-edge-restoration assist layer contains an element having an electronegativity not less than an electronegativity of Fe and Co, and not greater than an electronegativity of Mg.

9. The method of claim 8, further comprising forming an MTJ-edge-protection layer to surround the insulating MTJ-edge-restoration assist layer, wherein the MTJ-edge-protection layer comprises a dense insulating material.

10. The method of claim 9, wherein the MTJ-edge-protection layer contains an element having an electronegativity larger than that of the insulating MTJ-edge-restoration-assist layer.

11. The method of claim 1, wherein the forming forms the chemical damage to include an oxidation material, a nitridation material, or both, and wherein the transforming includes a de-oxidation, a de-nitridation, or de-water, or any combination thereof.

12. The method of claim 11, wherein the transforming includes applying a processing temperature above 200 degrees C.

13. The method of claim 12, wherein applying the processing temperature includes raising the edge region, while the edge region is exposed, to a temperature above 200 degrees C.

14. The method of claim 11, wherein the transforming includes an annealing process.

15. The method of claim 11, wherein the transforming is performed until the edge region with the chemical damage is transformed to a chemically restored peripheral edge region of the magnetic tunnel junction layer.

16. The method of claim 1, wherein the forming forms the chemical damage to include an oxidation material, and wherein the transforming includes a de-oxidation.

17. The method of claim 16 wherein the transforming is performed until the edge region with the chemical damage is transformed into a chemically restored peripheral edge region of the magnetic tunnel junction layer

18. The method of claim 17, wherein the magnetic tunnel junction layer is arranged facing a tunnel barrier layer having magnesium oxide (MgO),
wherein the magnetic tunnel junction layer includes iron (Fe), cobalt (Co), or both, and
wherein the de-oxidation includes forming an insulating MTJ-edge-restoration-assist layer to surround the oxidation material, wherein the insulating MTJ-edge-restoration assist layer contains an element having an electronegativity not less than an electronegativity of Fe and Co, and not greater than an electronegativity of Mg.

19. The method of claim 18, further comprising forming an insulating MTJ-edge-protection layer to surround the insulating MTJ-edge-restoration assist layer, wherein the insulating MTJ-edge-protection layer comprises a dense insulating material.

20. The method of claim 19, wherein the insulating MTJ-edge-protection layer contains an element having an electronegativity larger than that of the insulating MTJ-edge-restoration-assist layer.

21. The method of claim 17, wherein the magnetic tunnel junction layer is arranged facing a tunnel barrier layer having magnesium oxide,
wherein the magnetic tunnel junction layer includes iron (Fe), cobalt (Co),
wherein the de-oxidation comprises pulling oxygen from the oxidation material without pulling oxygen from the magnesium oxide of the tunnel barrier layer,
wherein said pulling oxygen comprises forming an insulating MTJ-edge-restoration-assist layer to surround the oxidation material, and
wherein the insulating MTJ-edge-restoration assist layer contains an element having an electronegativity not less than an electronegativity of Fe and Co, and not greater than an electronegativity of Mg.

22. The method of claim 21, further comprising forming an insulating MTJ-edge-protection layer to surround the insulating MTJ-edge-restoration assist layer, wherein the insulating MIT-edge-protection layer comprises a dense insulating material.

23. The method of claim 22, wherein the insulating MTJ-edge-protection layer contains an element having an electronegativity larger than that of the insulating MTJ-edge-restoration-assist layer.

24. A magnetic tunnel junction structure, comprising:
an MTJ layer having a peripheral edge; and
an insulating MTJ-edge-restoration-assist layer surrounding the peripheral edge of the MTJ layer, wherein
the insulating MTJ-edge-restoration-assist layer contains an element having an electronegativity not less than an electronegativity of Fe and Co, and not greater than an electronegativity of Mg.

25. The magnetic tunnel junction structure of claim 24, further comprising a tunnel barrier layer facing the MTJ layer, wherein the tunnel barrier layer includes magnesium oxide (MgO).

26. The magnetic tunnel junction structure of claim 25, further comprising an MTJ-edge-protection layer surrounding the insulating MTJ-edge-restoration-assist layer, wherein the MTJ-edge-protection layer comprises a dense insulating material and contains an element having an electronegativity larger than that of the insulating MTJ-edge-restoration-assist layer.

27. The magnetic tunnel junction structure of claim 24, wherein the MTJ layer includes a portion proximal to the peripheral edge formed by an oxidation or nitridation, or both, followed by a de-oxidation or de-nitridation, or both.

28. The magnetic tunnel junction structure of claim 24, wherein the MTJ layer is a pinned layer, wherein the magnetic tunnel junction structure further comprises:
an MTJ free layer having a peripheral edge surrounded by the insulating MTJ-edge-restoration-assist layer containing an element having an electronegativity not less than the electronegativity of Fe and Co, and not greater than the electronegativity of Mg.

29. The magnetic tunnel junction structure of claim 24, wherein the magnetic tunnel junction structure is integrated in at least one semiconductor die.

30. The magnetic tunnel junction structure of claim 24, further comprising a device, selected from the group consisting of a set top box, music player, video player, entertainment unit, navigation device, communications device, personal digital assistant (PDA), fixed location data unit, and a computer, into which the magnetic tunnel junction structure is integrated.

31. A computer readable tangible medium storing instructions executable by a computer that, when executed by the computer cause the computer to perform a method of repairing or reducing chemical damage of an edge region of a magnetic tunnel junction layer, the instructions comprising:
instructions that when executed cause the computer to form the magnetic tunnel junction layer having the edge region with a chemical damage; and
instructions that when executed cause the computer to transform at least a portion of the edge region with the chemical damage to a chemically restored edge portion.

32. The computer readable tangible medium of claim 31, wherein the instructions that when executed cause the computer to form the magnetic tunnel junction layer having the edge region with a chemical damage form the chemical damage to include an oxidation material, a nitridation material, or both; and
wherein the instructions that when executed cause the compute to transform at least a portion of the edge region with a chemical damage to the chemically restored edge portion cause the transforming to include ode-oxidation, ode-nitridation, or de-water, or any combination thereof.

33. A method for repairing or reducing chemical damage of an edge region of a magnetic tunnel junction layer, comprising:
step of forming the magnetic tunnel junction layer having the edge region with a chemical damage; and
step of transforming at least a portion of the edge region with the chemical damage to a chemically restored edge portion.

34. A method for fabricating a magnetic tunnel junction (MTJ) device, comprising:
providing a multi-layer structure including a substrate, a ferromagnetic pinned layer above the substrate, a tunnel barrier layer above the ferromagnetic pinned layer, a ferromagnetic free layer above the tunnel barrier layer, and a top conducting layer above the ferromagnetic free layer;
etching the multi-layer structure to form a pillar, the pillar including a portion of the ferromagnetic free layer, the portion having a chemically damaged peripheral edge region;
transforming the chemically damaged peripheral edge region to a chemically restored peripheral edge region, wherein the transforming includes a de-oxidation, a de-nitridation, or de-water, or any combination therefore; and
forming an insulating MTJ-edge-restoration-assist layer to surround the chemically restored peripheral edge region.

35. The method of claim 34, wherein the insulating MTJ-edge-restoration-assist layer contains an element having an electronegativity not less than an electronegativity of Fe and Co, and not greater than an electronegativity of magnesium (Mg).

36. The method of claim 34, further comprising forming an insulating MTJ-edge-protection layer to surround the insulating MTJ-edge-restoration-assist layer, wherein the MTJ-edge-protection layer comprises a dense insulating material.

37. An apparatus for repairing or reducing chemical damage to an edge region of a magnetic tunnel junction layer, comprising:
means for forming the magnetic tunnel junction layer having the edge region, wherein the means for forming is configured to form the edge region with an oxidation material or a nitridation material; and
means for transforming the oxidation material or the nitridation material to form a chemically restored peripheral edge region of the magnetic tunnel junction layer.

38. The apparatus of claim 37, wherein the means for transforming is configured to perform a de-oxidation, a de-nitridation, or de-water, or any combination thereof.

39. The apparatus of claim 37, further comprising means for transforming the chemically restored peripheral edge region into a chemically restored and protected edge region.
